(19) United States
(12) Patent Application Publication
(10) Pub. No.: US 2025/0287670 A1
(43) Pub. Date: Sep. 11, 2025

(54) MANUFACTURING METHOD OF POWER DEVICE HAVING DUAL POLYSILICON GATE

(71) Applicant: Richtek Technology Corporation, Zhubei City (TW)

(72) Inventors: Yu-Wei Hsu, Tainan (TW); Han-Chung Tai, Hsinchu (TW); Yong-Zhong Hu, Hsinchu (TW)

(21) Appl. No.: 18/670,861

(22) Filed: May 22, 2024

(30) Foreign Application Priority Data
Mar. 8, 2024 (TW) 113108620

(51) Int. Cl. H01L 29/40; H01L 21/266; H01L 21/306; H01L 21/308; H01L 29/66; H01L 29/78

(52) U.S. Cl. CPC H10D 64/117; H01L 21/266; H01L 21/30604; H01L 21/308; H10D 30/0281; H10D 30/65

(57) ABSTRACT

A manufacturing method of a power device having a dual polysilicon gate, including: forming a well in a substrate; forming a gate oxide layer; forming a polysilicon gate layer; forming a photo resist layer on the polysilicon gate layer to define a reduced surface field region, an enhanced drift region, and a field plate groove; etching the polysilicon gate layer to form the field plate groove; implanting a plurality of first and second conductivity type dopants in the substrate to form the reduced surface field region and the enhanced drift region; forming a field plate region in the field plate groove; forming another polysilicon gate layer which connects and overlays the polysilicon gate layer and the field plate region; and etching the polysilicon gate layers to form a first poly silicon gate region and a second poly silicon gate region, so as to form the dual polysilicon gate.

### CROSS REFERENCE

The present invention claims priority to TW 113108620 filed on Mar. 8, 2024.

### BACKGROUND OF THE INVENTION

### Field of Invention

The present invention relates to a manufacturing method of a power device having dual polysilicon gate, particularly, it relates to such power device having dual polysilicon gate that can eliminate sharp angles at an interface between a gate and a field oxide region.

### Description of Related Art

Referring to FIG. 1, which is a schematic cross-sectional view showing a prior art power device 10. As shown in FIG. 1, the power device 10 is formed in a substrate 11 and comprises a gate oxide region 12, a gate 13, a field oxide region 17, a spacer region 19, a body region 20, a source 21, a drain 22, and a shallow trench isolation (STI) region 23.

The power device 10 is a type of lateral double-diffused metal-oxide-semiconductor (LDMOS) device. In typical LDMOS devices, the most effective way to improve the device breakdown voltage and mitigate the hot carrier injection problem near the gate edge is to adopt a field plate structure, which can alleviate the local electric field crowding that causes early device breakdown. Although the traditional LOCOS field oxide region (as the field oxide region 17 shown in FIG. 1) is the simplest way to realize the field plate structure without additional masking, the LOCOS field oxide region may lead to several severe issues, such as high ON resistance and diffusion of dopants (boron, phosphorus) in the LDMOS device into the field oxide region during high-temperature processes.

Furthermore, there exist sharp angles at the interface between the gate 13 and the gate oxide region 12 and the field oxide region 17, which can cause process issues, such as voids or seams. Moreover, various oxide etching and re-deposition steps can aggravate the recession of the shallow trench isolation (STI) region 23. The aforementioned dopants (boron, phosphorus) diffusion into the field oxide region 17 also affects the device characteristics and reliability.

In view of the above, the present invention proposes a manufacturing method of a power device having a dual polysilicon gate, which can avoid damage to the shallow trench isolation or LOCOS field oxide region, eliminate the sharp angles at the interface between the gate and the field oxide region, reduce the ON resistance, and improve the device characteristics and reliability.

### SUMMARY OF THE INVENTION

From one perspective, the present invention provides a manufacturing method of a power device having a dual polysilicon gate, comprising: forming a well in a substrate; forming a gate oxide layer directly connected and fully covering the substrate; forming a first polysilicon gate layer directly connected and fully covering the gate oxide layer; forming a first photoresist layer on the first polysilicon gate layer by a first photolithography process step to simultaneously define a reduced surface field region, an enhanced drift region, and a field plate groove; etching the first polysilicon gate layer by using the first photoresist layer as an etching mask to form the field plate groove; implanting a plurality of first conductivity type dopants into the substrate by using the first photoresist layer as an implanting mask to form the reduced surface field region; implanting a plurality of second conductivity type dopants into the substrate by using the first photoresist layer as an implanting mask to form the enhanced drift region, wherein the first and second conductivity type dopants have opposite electrical properties; forming a field plate region in the field plate groove in a self-aligned process step; forming a second polysilicon gate layer directly connected to and fully covering the first polysilicon gate layer and the field plate region; and etching the first and second polysilicon gate layers to form a first polysilicon gate region and a second polysilicon gate region, so as to form the dual polysilicon gate; wherein a portion of the second polysilicon gate region is directly connected to and fully covers the first polysilicon gate region, and another portion of the second polysilicon gate region is directly connected to and covers a portion of the field plate region.

In one embodiment, the step of etching the first polysilicon gate layer to form the field plate groove by using the first photoresist layer as an etching mask is performed before the steps of implanting the plurality of first conductivity type dopants into the substrate by using the first photoresist layer as an implanting mask to form the reduced surface field region and implanting the plurality of second conductivity type dopants into the substrate by using the first photoresist layer as an implanting mask to form the enhanced drift region.

In one embodiment, the step of etching the first polysilicon gate layer to form the field plate groove by using the first photoresist layer as an etching mask is performed after the steps of implanting the plurality of first conductivity type dopants into the substrate by using the first photoresist layer as an implanting mask to form the reduced surface field region and implanting the plurality of second conductivity type dopants into the substrate by using the first photoresist layer as an implanting mask to form the enhanced drift region.

In one embodiment, the manufacturing method further comprises: forming a liner oxide layer by a deposition process step after forming the field plate groove, wherein the liner oxide layer fully covers the field plate groove.

In one embodiment, after forming the liner oxide layer, a liner oxide region and the field plate region are formed by a deposition process step and a chemical mechanical polishing process step, wherein the liner oxide region fully covers the field plate groove.

In one embodiment, after forming the liner oxide layer, an anisotropic etching process step is performed to etch the liner oxide layer to form a plurality of spacer oxide regions, wherein the plural spacer oxide regions cover a plurality of sidewalls of the field plate groove respectively but does not cover a bottom of the field plate groove.

In one embodiment, the manufacturing method further comprises: forming a body region in the substrate, wherein a portion of the body region is located directly below a portion of the first polysilicon gate region; and forming a source and a drain in the substrate below the dual polysilicon gate on both sides, wherein the source is located in the body region.

From another perspective, the present invention provides a manufacturing method of a power device having a dual polysilicon gate, comprising: forming a well in a substrate; forming a gate oxide layer directly connected and fully covering the substrate; forming a first polysilicon gate layer directly connected and fully covering the gate oxide layer; forming a first photoresist layer on the first polysilicon gate layer in a first photolithography process step to simultaneously define a reduced surface field region, an enhanced drift region, and a field plate groove; implanting a plurality of first conductivity type dopants into the substrate by using the first photoresist layer as an implanting mask to form the reduced surface field region; implanting a plurality of second conductivity type dopants into the substrate by using the first photoresist layer as an implanting mask to form the enhanced drift region, wherein the first and second conductivity type dopants have opposite electrical properties; implanting oxygen ions into the first polysilicon gate layer in an oxygen ion implantation process step to form the field plate region by using the first photoresist layer as an implanting mask; forming a second polysilicon gate layer directly connected to and fully covering the first polysilicon gate layer and the field plate region; and etching the first and second polysilicon gate layers to form a first polysilicon gate region and a second polysilicon gate region, so as to form the dual polysilicon gate; wherein a portion of the second polysilicon gate region is directly connected to and fully covers the first polysilicon gate region, and another portion of the second polysilicon gate region is directly connected to and covers a portion of the field plate region.

In one embodiment, the manufacturing method further includes: forming a body region in the substrate, wherein a portion of the body region is located directly below a portion of the first polysilicon gate region; and forming a source and a drain in the substrate below the dual polysilicon gate on both sides, wherein the source is located in the body region.

The advantage of the present invention is that it can precisely control the profile and thickness of the field plate region, and since the field plate region does not require etching, there are no issues with oxide damage or purity.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a schematic cross-sectional view showing a prior art power device 10.

FIGS. 2A-2J are schematic cross-sectional views showing a manufacturing method of a power device 30 having a dual polysilicon gate according to an embodiment of the present invention.

FIGS. 3A-3H are schematic cross-sectional views showing a manufacturing method of a power device 50 having a dual polysilicon gate according to an embodiment of the present invention.

FIGS. 4A-4I are schematic cross-sectional views showing a manufacturing method of a power device 70 having a dual polysilicon gate according to an embodiment of the present invention.

FIGS. 5A-5G are schematic cross-sectional views showing a manufacturing method of a power device 90 having a dual polysilicon gate according to an embodiment of the present invention.

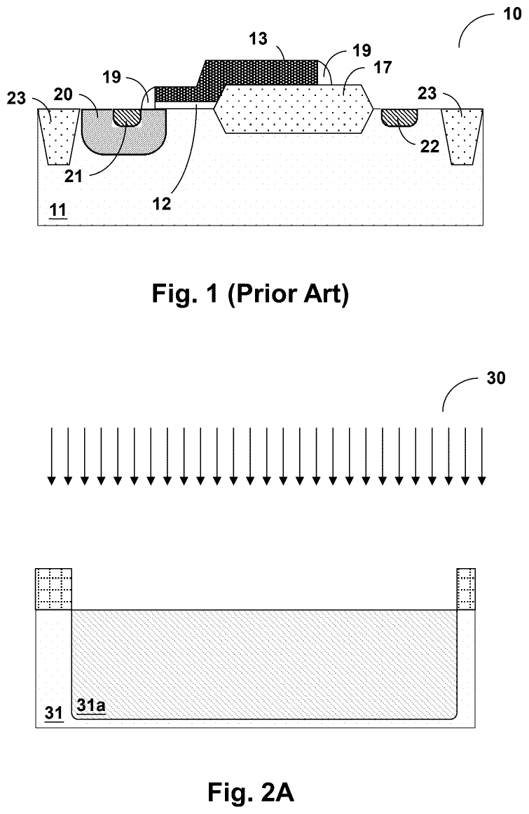

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

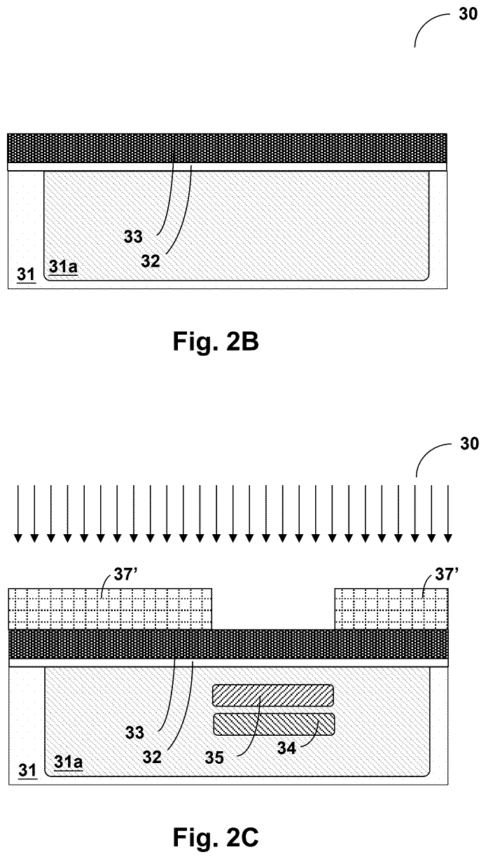

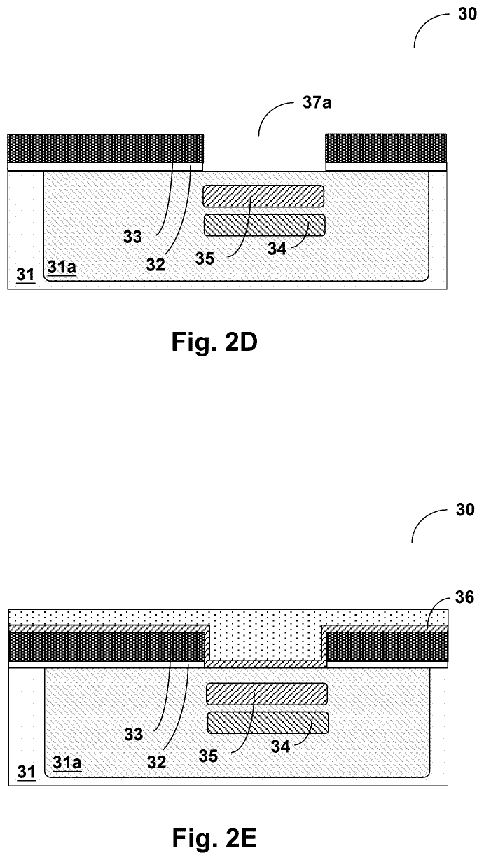

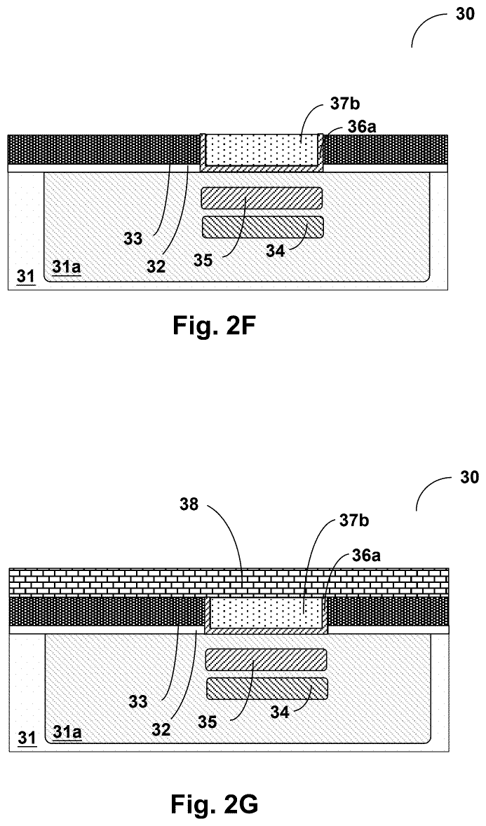

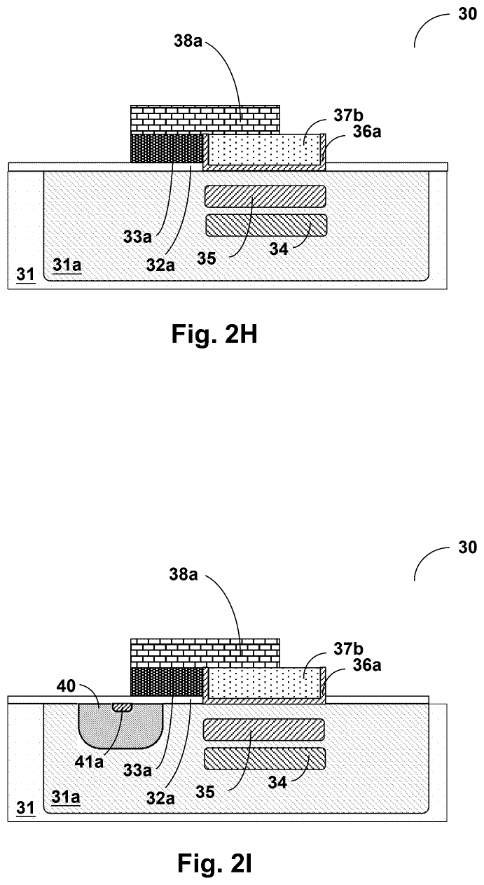

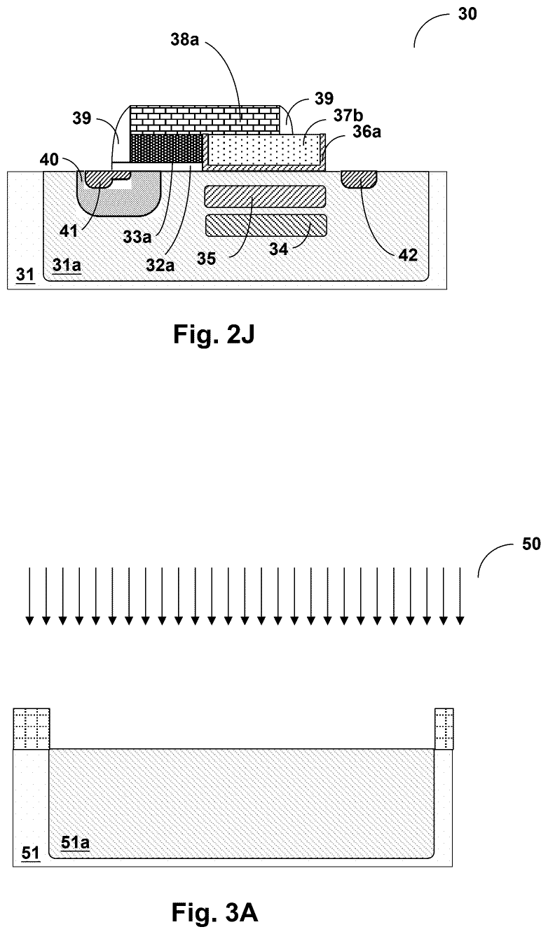

Please refer to FIGS. 2A-2J, which show schematic cross-sectional views of a manufacturing method of a power device 30 having a dual polysilicon gate according to an embodiment of the present invention. The power device 30 having a dual polysilicon gate comprises: a substrate 31, a well 31a, a gate oxide region 32a, a first polysilicon gate region 33a, a reduced surface field region 34, an enhanced drift region 35, a liner oxide region 36a, a field plate region 37b, a second polysilicon gate region 38a, a gate spacer 39, a body region 40, a source 41, and a drain 42. As shown in FIG. 2A, a substrate 31 is provided first, and a well 31a is formed in the substrate 31. In one embodiment, a photoresist layer is formed on the substrate 31 in a photolithography process step to define the well 31a. Then, as shown in FIG. 2A, using the photoresist layer as a mask, for example, in an ion implantation process step, a plurality of impurities are implanted into the substrate 31 in the form of accelerated ions, as indicated by multiple arrows in FIG. 2A, to form the well 31a.

Next, as shown in FIG. 2B, a gate oxide layer 32 is formed directly connected to and fully covering the substrate 31. In one embodiment, the gate oxide layer 32 is formed by a thermal oxidation process step. Then, as shown in FIG. 2B, a first polysilicon gate layer 33 is formed directly connected to and fully covering the gate oxide layer 32. In one embodiment, the polysilicon gate layer 33 is formed by a deposition process step. Subsequently, as shown in FIG. 2C, for example, in a first photolithography process step, a first photoresist layer 37′ is formed on the first polysilicon gate layer 33 to simultaneously define the reduced surface field region 34, the enhanced drift region 35, and the field plate groove 37a. Next, as shown in FIG. 2C, using the first photoresist layer 37′ as a mask, for example, in an ion implantation process step, a plurality of first conductivity type dopants are implanted into the substrate 31 in the form of accelerated ions, as indicated by multiple arrows in FIG. 2C, to form the reduced surface field region 34.

Then, as shown in FIG. 2C, using the first photoresist layer 37′ as a mask, for example, in an ion implantation process step, a plurality of second conductivity type dopants are implanted into the substrate 31 to form the enhanced drift region 35. It should be noted that the first conductivity type dopants and the second conductivity type dopants have opposite electrical properties. Next, as shown in FIGS. 2C and 2D, using the first photoresist layer 37′ as a mask, the first polysilicon gate layer 33 is etched to form the field plate groove 37a. Subsequently, as shown in FIGS. 2E and 2F, for example, in a self-aligned process step, the field plate region 37b is formed in the field plate groove 37a. In one embodiment, as shown in FIGS. 2D and 2E, after forming the field plate groove 37a, for example, in a deposition process step, a liner oxide layer 36 is formed, wherein the liner oxide layer 36 fully covers the field plate groove 37a. Then, as shown in FIGS. 2E and 2F, after forming the liner oxide layer 36, for example, in a deposition process step and a chemical mechanical polishing process step, the liner oxide region 36a and the field plate region 37b are formed, wherein the liner oxide region 36a fully covers the field plate groove 37a. In one embodiment, the field plate region 37b comprises a silicon oxide layer, a silicon nitride layer, a silicon oxynitride layer, and/or a high-k dielectric layer.

Next, as shown in FIG. 2G, a second polysilicon gate layer 38 is formed directly connected to and fully covering the first polysilicon gate layer 33 and the field plate region 37b. Then, as shown in FIG. 2H, for example, in a photolithography process step and an anisotropic etching process step, the first polysilicon gate layer 33 and the second polysilicon gate layer 38 are etched to form a first polysilicon gate region 33a and a second polysilicon gate region 38a, thereby forming the dual polysilicon gate. As shown in FIG. 2H, a portion of the second polysilicon gate region 38a is directly connected to and fully covers the first polysilicon gate region 33a, and another portion of the second polysilicon gate region 38a is directly connected to and covers a portion of the field plate region 37b. Then, as shown in FIG. 2I, for example, in an ion implantation process step, a plurality of first conductivity type dopants are implanted into the substrate 31 to form the body region 40, wherein a portion of the body region 40 is located directly below a portion of the first polysilicon gate region 33a. Additionally, as shown in FIG. 2I, for example, in an ion implantation process step, a plurality of second conductivity type dopants are implanted into the substrate 31 to form an extension region 41a of the source 41. The extension region 41a is a part of the source 41 and is located directly below the gate spacer 39 on the side near the source 41 formed subsequently.

Next, as shown in FIG. 2J, two gate spacers 39 is formed respectively on both sides of the dual polysilicon gate formed by the first polysilicon gate region 33a and the second polysilicon gate region 38a. Subsequently, as shown in FIG. 2J, the source 41 and the drain 42 are formed in the substrate 31 below both sides of the dual polysilicon gate, wherein the source 41 is located in the body region 40.

The substrate 31 may be, but is not limited to, a P-type or N-type semiconductor substrate. This is well-known to those skilled in the art and is not described in detail here.

The well 31a is of the first conductivity type. For example, in an ion implantation process step, N-type or P-type dopants are implanted into their respective defined regions in the form of accelerated ions. This is well-known to those skilled in the art and is not described in detail here. The first conductivity type may be P-type or N-type; when the first conductivity type is P-type, the second conductivity type is N-type; when the first conductivity type is N-type, the second conductivity type is P-type.

In one embodiment, as shown in FIGS. 2C and 2D, the step of etching the first polysilicon gate layer 33 to form the field plate groove 37a using the first photoresist layer 37′ as a mask is performed after the steps of implanting the plurality of first conductivity type dopants into the substrate 31 to form the reduced surface field region 34 and implanting the plurality of second conductivity type dopants into the substrate 31 to form the enhanced drift region 35 using the first photoresist layer 37′ as a mask.

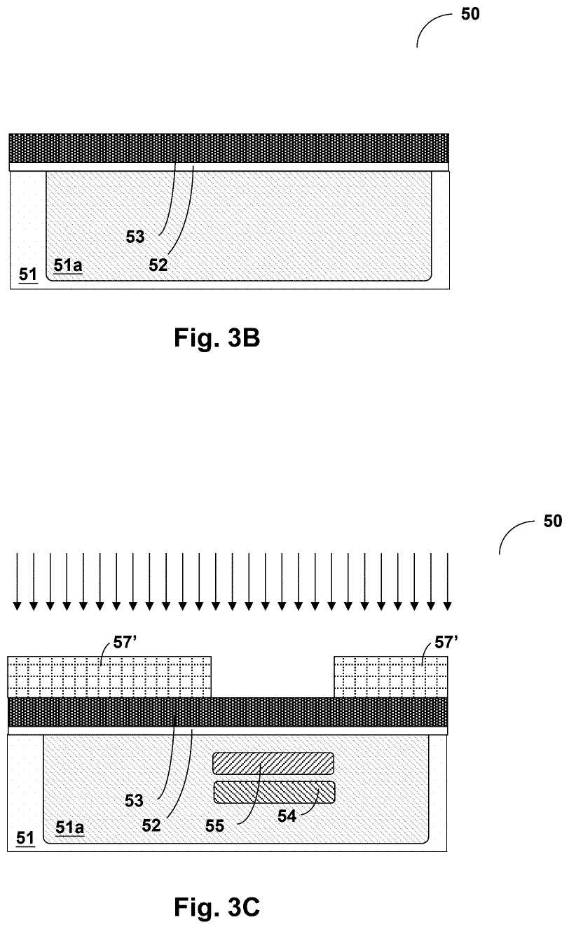

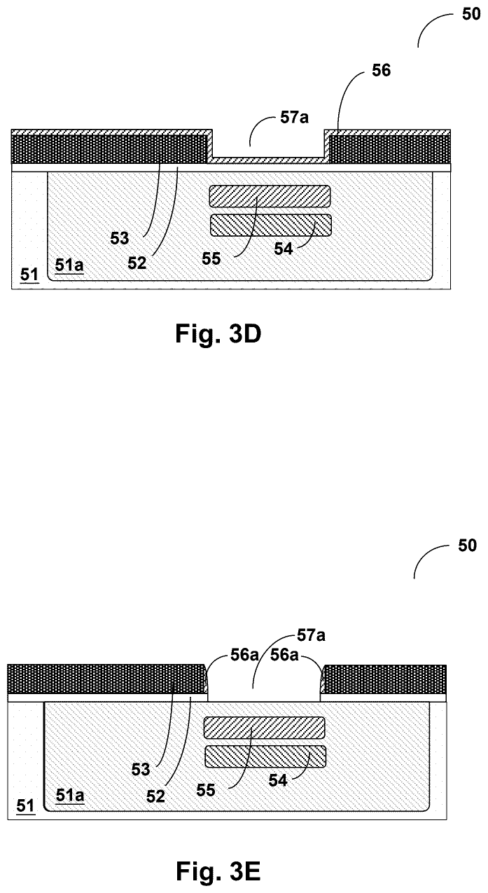

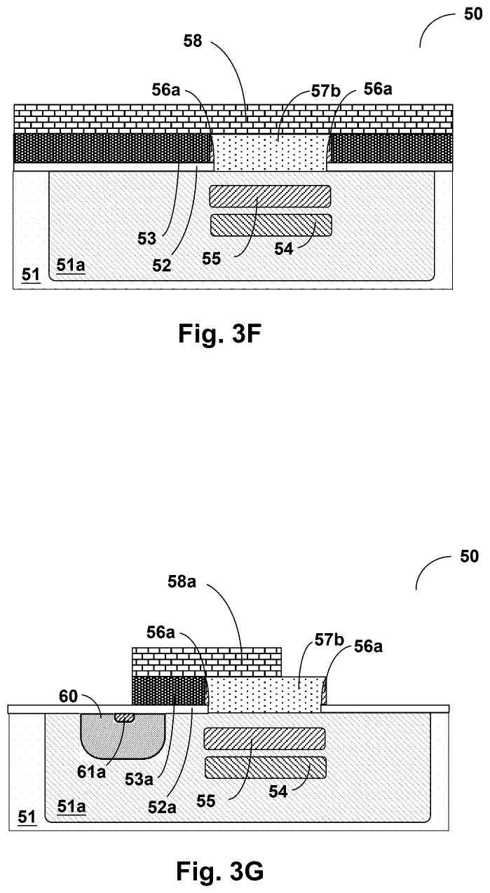

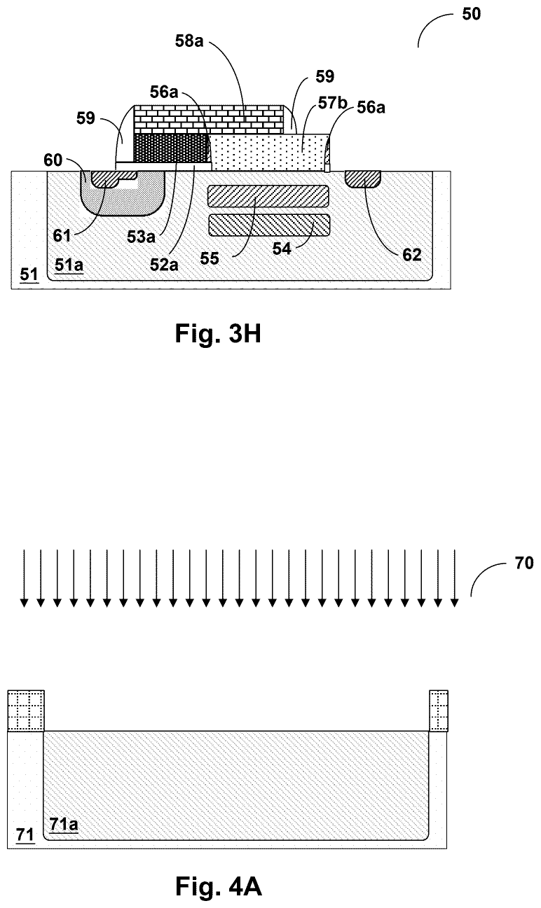

FIGS. 3A-3H are schematic cross-sectional views showing a manufacturing method of a power device 50 having a dual polysilicon gate according to an embodiment of the present invention. The power device 50 having a dual polysilicon gate comprises: a substrate 51, a well 51a, a gate oxide region 52a, a first polysilicon gate region 53a, a reduced surface field region 54, an enhanced drift region 55, a plurality of spacer oxide regions 56a, a field plate region 57b, a second polysilicon gate region 58a, a gate spacer 59, a body region 60, a source 61, and a drain 62. This embodiment is similar to the embodiment shown in FIGS. 2A-2J, with the difference that, as shown in FIGS. 3D and 3E, after forming the liner oxide layer 56, an anisotropic etching process step is performed to etch the liner oxide layer 56 to form the plural spacer oxide regions 56a, wherein the plural spacer oxide regions 56a respectively cover plural the sidewalls of the field plate groove 57a without covering the bottom of the field plate groove 57a. Next, as shown in FIG. 3F, after forming the plural spacer oxide regions 56a, a deposition process step and a chemical mechanical polishing process step are performed to form the field plate region 57b. In this embodiment, for descriptions related to the gate oxide layer 52, the first polysilicon gate layer 53, the liner oxide layer 56, the first photoresist layer 57′, the field plate groove 57a, the second polysilicon gate layer 58, and the extension region 61a, please refer to the descriptions of the gate oxide layer 32, the first polysilicon gate layer 33, the liner oxide layer 36, the first photoresist layer 37′, the field plate groove 37a, the second polysilicon gate layer 38, and the extension region 41a in the embodiment shown in FIGS. 2A-2J.

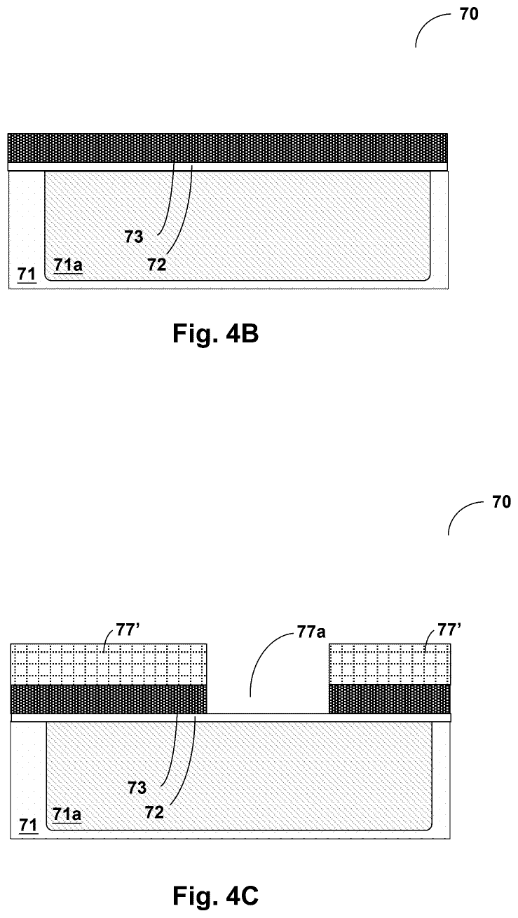

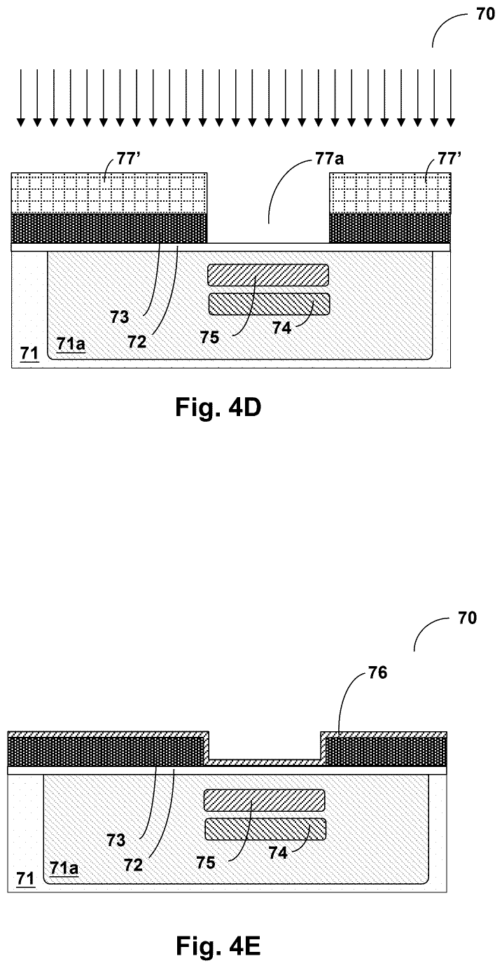

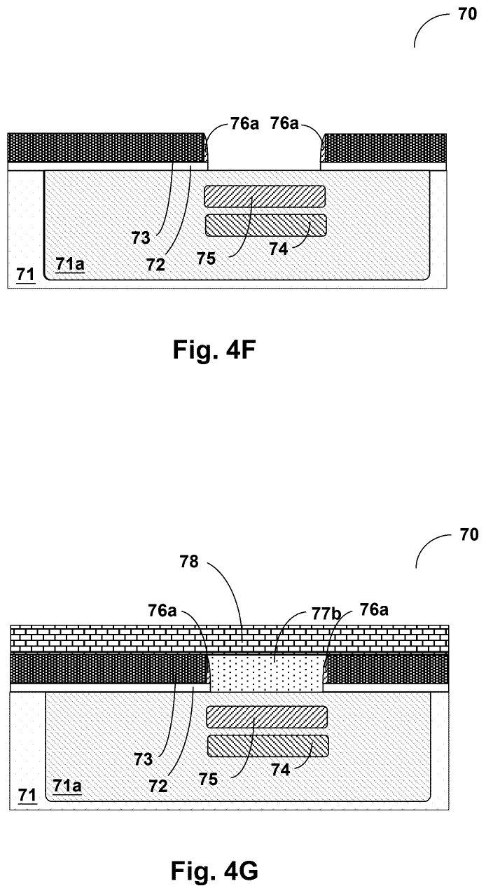

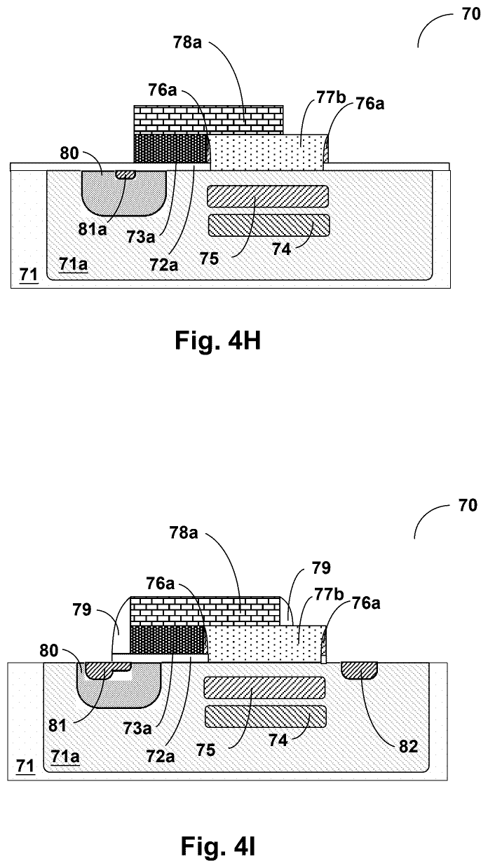

FIGS. 4A-4I are schematic cross-sectional views showing a manufacturing method of a power device 70 having a dual polysilicon gate according to an embodiment of the present invention. The power device 70 having a dual polysilicon gate comprises: a substrate 71, a well 71a, a gate oxide region 72a, a first polysilicon gate region 73a, a reduced surface field region 74, an enhanced drift region 75, a plurality of spacer oxide regions 76a, a field plate region 77b, a second polysilicon gate region 78a, a gate spacer 79, a body region 80, a source 81, and a drain 82. This embodiment is similar to the embodiment shown in FIGS. 3A-3H, with the difference that, as shown in FIGS. 4C and 4D, the step of etching the first polysilicon gate layer 73 to form the field plate groove 77a using the first photoresist layer 77′ as a mask is performed before the steps of implanting the plurality of first conductivity type dopants into the substrate 71 to form the reduced surface field region 74 and implanting the plurality of second conductivity type dopants into the substrate 71 to form the enhanced drift region 75 using the first photoresist layer 77′ as a mask. In this embodiment, for descriptions related to the gate oxide layer 72, the first polysilicon gate layer 73, the liner oxide layer 76, the first photoresist layer 77′, the field plate groove 77a, the second polysilicon gate layer 78, and the extension region 81a, please refer to the descriptions of the gate oxide layer 32, the first polysilicon gate layer 33, the liner oxide layer 36, the first photoresist layer 37′, the field plate groove 37a, the second polysilicon gate layer 38, and the extension region 41a in the embodiment shown in FIGS. 2A-2J.

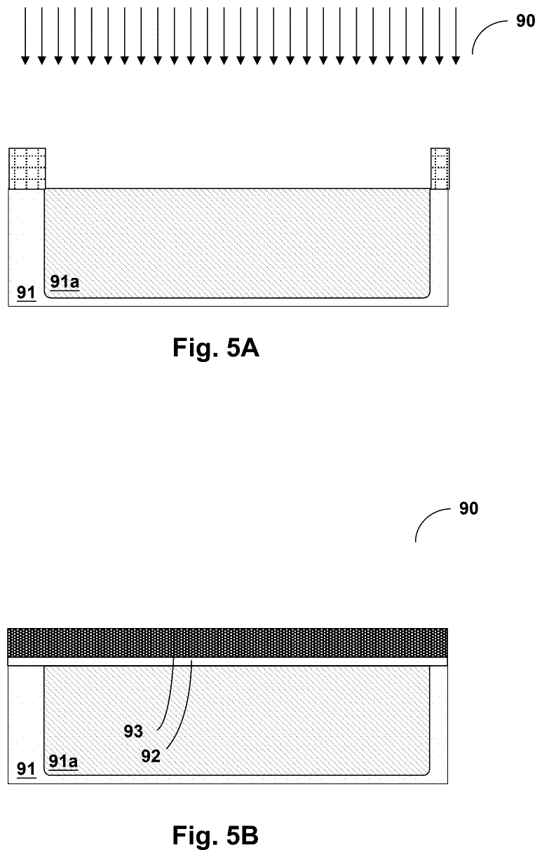

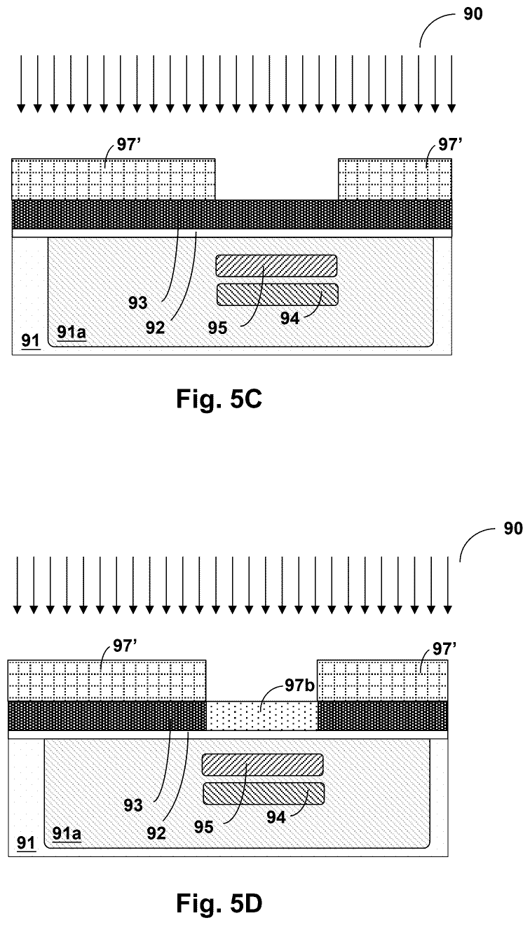

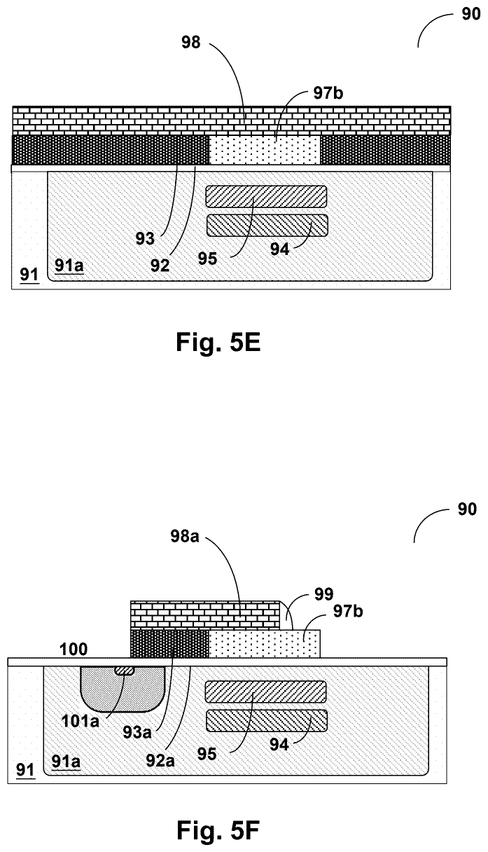

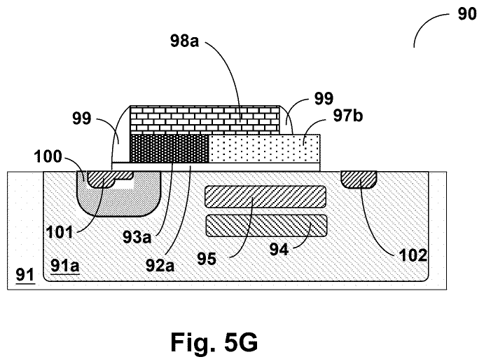

FIGS. 5A-5G are schematic cross-sectional views showing a manufacturing method of a power device 90 having a dual polysilicon gate according to an embodiment of the present invention. The power device 90 having a dual polysilicon gate comprises: a substrate 91, a well 91a, a gate oxide region 92a, a first polysilicon gate region 93a, a reduced surface field region 94, an enhanced drift region 95, a field plate region 97b, a second polysilicon gate region 98a, a gate spacer 99, a body region 100, a source 101, and a drain 102. This embodiment is similar to the embodiment shown in FIGS. 2A-2I, with the difference that, as shown in FIG. 5D, the oxygen ions are implanted into the first polysilicon gate layer 93 using the first photoresist layer 97′ as a mask, for example, in an oxygen ion implantation process step to form the field plate region 97b, and this embodiment does not require forming a liner oxide region or spacer oxide regions. In this embodiment, for descriptions related to the gate oxide layer 92, the first polysilicon gate layer 93, the first photoresist layer 97′, the field plate groove 97a, the second polysilicon gate layer 98, and the extension region 101a, please refer to the descriptions of the gate oxide layer 32, the first polysilicon gate layer 33, the liner oxide layer 36, the first photoresist layer 37′, the field plate groove 37a, the second polysilicon gate layer 38, and the extension region 41a in the embodiment shown in FIGS. 2A-2J.

In summary, the present invention can precisely control the profile and thickness of the field plate region, and since the field plate region does not require etching, there are no issues with oxide damage or purity.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography process step is not limited to the mask technology but it can also include electron beam lithography, immersion lithography, etc. Therefore, in the same spirit of the present invention, those skilled in the art can t various equivalent variations and various combinations, and there are many combinations thereof, and the description will not be repeated here. The scope of the present invention should include what are defined in the claims and the equivalents.

What is claimed is:

1. A manufacturing method of a power device having a dual polysilicon gate, comprising:
forming a well in a substrate;
forming a gate oxide layer directly connected and fully covering the substrate;
forming a first polysilicon gate layer directly connected and fully covering the gate oxide layer;
forming a first photoresist layer on the first polysilicon gate layer by a first photolithography process step to simultaneously define a reduced surface field region, an enhanced drift region, and a field plate groove;
etching the first polysilicon gate layer by using the first photoresist layer as an etching mask to form the field plate groove;
implanting a plurality of first conductivity type dopants into the substrate by using the first photoresist layer as an implanting mask to form the reduced surface field region;
implanting a plurality of second conductivity type dopants into the substrate by using the first photoresist layer as an implanting mask to form the enhanced drift region, wherein the first and second conductivity type dopants have opposite electrical properties;
forming a field plate region in the field plate groove in a self-aligned process step;
forming a second polysilicon gate layer directly connected to and fully covering the first polysilicon gate layer and the field plate region; and
etching the first and second polysilicon gate layers to form a first polysilicon gate region and a second polysilicon gate region, so as to form the dual polysilicon gate;
wherein a portion of the second polysilicon gate region is directly connected to and fully covers the first polysilicon gate region, and another portion of the second polysilicon gate region is directly connected to and covers a portion of the field plate region.

2. The manufacturing method of claim 1, wherein the step of etching the first polysilicon gate layer to form the field plate groove by using the first photoresist layer as an etching mask is performed before the steps of implanting the plurality of first conductivity type dopants into the substrate by using the first photoresist layer as an implanting mask to form the reduced surface field region and implanting the plurality of second conductivity type dopants into the substrate by using the first photoresist layer as an implanting mask to form the enhanced drift region.

3. The manufacturing method of claim 1, wherein the step of etching the first polysilicon gate layer to form the field plate groove by using the first photoresist layer as an etching mask is performed after the steps of implanting the plurality of first conductivity type dopants into the substrate by using the first photoresist layer as an implanting mask to form the reduced surface field region and implanting the plurality of second conductivity type dopants into the substrate by using the first photoresist layer as an implanting mask to form the enhanced drift region.

4. The manufacturing method of claim 1, further comprising: forming a liner oxide layer by a deposition process step after forming the field plate groove, wherein the liner oxide layer fully covers the field plate groove.

5. The manufacturing method of claim 4, wherein after forming the liner oxide layer, a liner oxide region and the field plate region are formed by a deposition process step and a chemical mechanical polishing process step, wherein the liner oxide region fully covers the field plate groove.

6. The manufacturing method of claim 4, wherein after forming the liner oxide layer, an anisotropic etching process step is performed to etch the liner oxide layer to form a plurality of spacer oxide regions, wherein the plural spacer oxide regions cover a plurality of sidewalls of the field plate groove respectively but does not cover a bottom of the field plate groove.

7. The manufacturing method of claim 1, wherein the field plate region comprises a silicon oxide layer, a silicon nitride layer, a silicon oxynitride layer, and/or a high-k dielectric layer.

8. The manufacturing method of claim 1, further comprising:
forming a body region in the substrate, wherein a portion of the body region is located directly below a portion of the first polysilicon gate region; and
forming a source and a drain in the substrate below the dual polysilicon gate on both sides, wherein the source is located in the body region.

9. A manufacturing method of a power device having a dual polysilicon gate, comprising:
forming a well in a substrate;
forming a gate oxide layer directly connected and fully covering the substrate;
forming a first polysilicon gate layer directly connected and fully covering the gate oxide layer;
forming a first photoresist layer on the first polysilicon gate layer in a first photolithography process step to simultaneously define a reduced surface field region, an enhanced drift region, and a field plate groove;
implanting a plurality of first conductivity type dopants into the substrate by using the first photoresist layer as an implanting mask to form the reduced surface field region;
implanting a plurality of second conductivity type dopants into the substrate by using the first photoresist layer as an implanting mask to form the enhanced drift region, wherein the first and second conductivity type dopants have opposite electrical properties;
implanting oxygen ions into the first polysilicon gate layer in an oxygen ion implantation process step to form the field plate region by using the first photoresist layer as an implanting mask;
forming a second polysilicon gate layer directly connected to and fully covering the first polysilicon gate layer and the field plate region; and
etching the first and second polysilicon gate layers to form a first polysilicon gate region and a second polysilicon gate region, so as to form the dual polysilicon gate;
wherein a portion of the second polysilicon gate region is directly connected to and fully covers the first polysilicon gate region, and another portion of the second polysilicon gate region is directly connected to and covers a portion of the field plate region.

10. The manufacturing method of claim 9, further comprising:
forming a body region in the substrate, wherein a portion of the body region is located directly below a portion of the first polysilicon gate region; and
forming a source and a drain in the substrate below the dual polysilicon gate on both sides, wherein the source is located in the body region.
